(19) United States
(12) Patent Application Publication
(10) Pub. No.: US 2009/0087564 A1
(43) Pub. Date: Apr. 2, 2009

(54) Substrate processing system

(76) Inventors: Takao Horiuchi, Tokyo (JP); Azumi Horiuchi, Palo Alto, CA (US); Hiroaki Ogamino, Tokyo (JP); Yasuhiro Niimura, Tokyo (JP); Hiroshi Hattori, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 12/289,066

(22) Filed: Oct. 20, 2008

Related U.S. Application Data
(62) Division of application No. 10/559,669, filed on Dec. 6, 2005.

(30) Foreign Application Priority Data
Jul. 4, 2003 (JP) 2003-191756

(51) Int. Cl. C23C 16/455

(52) U.S. Cl. 427/255.28

(57) ABSTRACT

A substrate processing system which utilizes reactive substances or carrier gases to process the surface of a substrate is provided. The system includes a gas supply source for supplying a process gas containing a reactive substance, a reservoir tank connected to the gas supply source for reserving the process gas, a reactor for exposing a substrate placed therein to the process gas, a first circulation pipe for circulating the process gas inside the reactor to the reservoir tank, a second circulation pipe for circulating at least part of the process gas in the reservoir tank to the reactor, and a flow regulating valve disposed in the second circulation pipe for controlling the amount of process gas introduced into the reactor.

This is a divisional of U.S. application Ser. No. 10/559,669, filed Dec. 6, 2005, which is the National Stage of International Application PCT/JP2004/009577, filed Jun. 30, 2004.

### BACKGROUND OF THE INVENTION

1. Technical Field

This invention relates to a substrate processing system and particularly to a substrate processing system for processing the surface of the substrate which is exposed to a reactive substance.

2. Description of Related Art

Conventionally, in a substrate surface processing method using gases, such as CVD (Chemical Vapor Deposition), the surface of a substrate is exposed to a process gas containing a reactive substance for a relatively long time for processing, such as doping.

If there is no change in the properties of the process gas after reaction, or if the process gas is reusable irrespective of its property change, an attempt should be made to reuse the process gas. Such reuse of the process gas is favorable in terms of reducing harmful effects on the substrate itself, humans, or the environment, as well as in terms of cost reduction.

A technique of reusing exhaust gas for sealing the shaft of a vacuum pump is known (See JP-A-2000-9037, for example), but this technique is insufficient in terms of effective utilization of the reactive substance contained in the gas. Further, a semiconductor manufacturing system is known in which a gas discharged from a vacuum chamber is recycled to the vacuum chamber (See JP-A-Hei 9-251981, for example). This system has a problem that it is unable to handle intermittent gas flow talthough it is able to handle a process in which a fixed amount of gas flows continuously.

In view of the foregoing problems in the prior art, it is an object of the present invention to provide a substrate processing system which efficiently utilizes reactive substances or carrier gases necessary for processing the surface of a substrate, simplifies equipment for gas transfer, and saves energy.

### BRIEF SUMMARY OF THE INVENTION

In order to solve the above-identified problems in the prior art, a first embodiment of the invention is a substrate processing system which comprises: a gas supply source for supplying a process gas containing a reactive substance; a reservoir tank connected to the gas supply source for reserving the process gas; a reactor for exposing a substrate placed therein to the process gas; a first circulation pipe for introducing the process gas inside the reactor into the reservoir tank; a second circulation pipe for introducing at least part of the process gas in the reservoir tank into the reactor; and a flow regulating valve disposed in the second circulation pipe for regulating the amount of process gas introduced into the reactor. Here, the term “reactive” means not only chemical reactions, but also phenomena in which the surface of a substrate changes from an original condition due to adhering of a substance or the like.

Since the process gas containing a reactive substance required to process the surface of a substrate can be circulated, the process gas can be reused efficiently. Also, the equipment for gas transfer can be simplified, and energy can be saved. Further, since the discharged gas is temporarily reserved in a reservoir tank and any amount of gas can be reused, the substrate processing system according to an embodiment of the present invention is able to handle an intermittent gas flow.

One preferred embodiment of the invention is a substrate processing system further comprising a pump for drawing the process gas from the reactor and then introducing the drawn process gas into the reservoir tank through the first circulation pipe.

According to the invention as described above, a process gas containing a reactive substance required to process the surface of a substrate can be circulated, so that the process gas can be reused efficiently. Also, equipment for gas transfer can be simplified and energy savings can be effected.

This application claims priority to Japanese patent application No. 2003-191756, filed in Japan on Jul. 4, 2003, which is entirely incorporated herein by reference.

This invention will be more completely described in the following detailed description. However, the specific examples in the following description are preferred embodiments of the invention presented for the purpose of explanation only. Additional applications of this invention will become clear from the following detailed description. For those skilled in the art, it will become apparent that various changes and modifications can be made within the scope and spirit of the invention.

The applicant has no intention of dedicating to the public any of the described embodiments. Of the disclosed modifications and alternatives, those which may not be literally covered by the claims shall be part of the invention under the doctrine of equivalents.

### BRIEF DESCRIPTION OF THE DRAWING

FIG. 1 is a schematic diagram, illustrating the overall construction of a substrate processing system according to one embodiment of the invention.

### DETAILED DESCRIPTION OF THE INVENTION

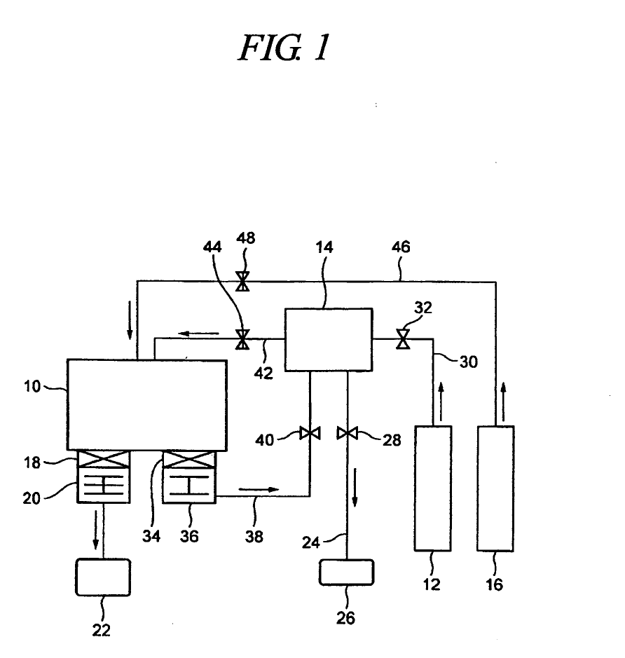

Now, an embodiment of the substrate processing system according to the invention is described in detail with reference to FIG. 1. FIG. 1 is a schematic diagram illustrating the overall construction of a substrate processing system according to one embodiment of the invention. As shown in FIG. 1, the substrate processing system according to this embodiment comprises: a reactor 10 in which a substrate to be processed is placed; a first gas supply source 12 for supplying a first process gas containing a reactive substance to the reactor 10; a reservoir tank 14 connected to the first gas supply source 12; a second gas supply source 16 for supplying a second process gas to the reactor 10; a turbo-molecular pump 20 connected to the reactor 10 through a valve 18; and a dry pump 22 disposed downstream of the turbo-molecular pump 20.

Another dry pump 26 is connected to the reservoir tank 14 through a pipe 24 to reduce the pressure within the reservoir tank 14. A valve 28 is disposed in the pipe 24. Also, a valve 32 is disposed in a pipe 30 which connects the reservoir tank 14 and first gas supply source 12.

Also, a pressure pump 36 is connected to the reactor 10 through a valve 34. The pressure pump 36 is connected to the reservoir tank 14 through (a first) circulation pipe 38 in which a valve 40 is disposed. Also, the reservoir tank 14 is connected to the reactor 10 through (a second) circulation pipe 42. A flow regulating valve 44, for regulating the amount of first process gas introduced into the reactor 10, is disposed in the circulation pipe 42. The process gas inside the reactor 10 is introduced into the reservoir tank 14 through the circulation pipe 38, and at least part of the process gas inside of the reservoir tank 14 is introduced into the reactor 10 through the circulation pipe 42. Further, the second gas supply source 16 is connected to the reactor 10 through a pipe 46. A flow regulating valve 48 for regulating the amount of second process gas to be introduced into the reactor 10 is disposed in pipe 46.

Now, a method of processing a substrate using the substrate processing system of the foregoing construction will be described. First, the valve 32 and the valve 28 are opened and the flow regulating valve 44 and the valve 40 are closed. Under this condition, the dry pump 26 is driven to reduce the pressure inside of the reservoir tank 14 to a given value (Pr), and the first process gas flows from the first gas supply source 12 into the reservoir tank 14.

In this embodiment, the dry pump 26 is used to reduce the pressure inside of the reservoir tank 14. However, the turbo-molecular pump 20 and dry pump 22 may be used in place of the dry pump 26 to reduce the pressure inside of the reservoir tank 14 while the valve 18 and flow regulating valve 44 or valves 18, 34, 40 are opened. Also, if the pressure in the first gas supply source (gas cylinder) 12 is sufficiently high, the first process gas can be introduced into the reservoir tank 14 without the use of either dry pumps 22, 26 or turbo-molecular pump 20. Although in this embodiment, a process gas containing a reactive substance is supplied from the first gas supply source 12, a carrier gas may be supplied from the first gas supply source 12 and this carrier gas and a reactive substance may be mixed together downstream of the first gas supply source 12 to form a first process gas.

Thereafter, the valve 18 is opened, and the turbo-molecular pump 20 and dry pump 22 are driven to reduce the pressure inside of the reactor 10 to a value not higher than the internal pressure Pr in the reservoir tank 14. Then, the valve 18 is closed to form a tightly closed space inside of the reactor 10.

Under this condition, if valves 34, 40, and 44 are opened with the other valves closed, the first process gas in the reservoir tank 14 at a higher pressure flows into the reactor 10 at a lower pressure and, thus, the first process gas is introduced in the reactor 10. At this time, the opening of the flow regulating valve 44 is controlled to regulate the amount of the process gas introduced into the reactor 10.

The substrate placed inside of the reactor 10 is exposed to the first process gas introduced into the reactor 10, and a reactive substance contained in the first process gas adheres on the surface of the substrate (adhering process). Since a circulation system of the first process gas is defined by the reactor 10, pressure pump 36, circulation pipe 38, reservoir tank 14, and circulation pipe 42, when the pressure pump 36 is driven to generate a pressure difference between the reactor 10 and reservoir tank 14, the first process gas can be circulated continuously. At this time, the valve 40 may be opened and closed to intermittently circulate the first process gas.

Although, in this embodiment, the first process gas is circulated using the pressure pump 36, it may be circulated using a circulation mechanism other than this pump. Also, an elimination device (for example, a filter) for eliminating unfavorable substances (such as condensates) in the process gas may be provided in the circulation pipe 38 or 42.

In this embodiment as described above, the first process gas from the first gas supply source 12 is reused through the foregoing circulation system. Therefore, a process gas can be reused efficiently, equipment for the gas transfer can be simplified, and energy can be saved.

When reuse of the first process gas has reached a limit or when the properties of the first process gas have become unsuitable for reuse, the valve 28 is opened, and the dry pump 26 is driven to discharge the process gas to the outside.

On the other hand, when the second process gas is used, the second process gas is introduced into the reactor 10 from the second gas supply source 16 through the flow regulating valve 48, for the reaction in the reactor 10. Thereafter, the flow regulating valve 48 is closed and the valve 18 disposed upstream of the turbo-molecular pump 20 is opened, to drive the turbo-molecular pump 20 and dry pump 22, so that, after the reactions, the second process gas is discharged outside the system after passing through an elimination device (not shown).

After completion of a series of processes, the processed substrate is removed from the reactor 10. Another substrate is placed inside the reactor 10, and the foregoing procedure is repeated. The substrates may be loaded in the reactor 10 one by one, or in a batch.

Although, in this embodiment, an example has been described in which a first gas supply source 12 and a second gas supply source 16 are provided, only the first gas supply source 12 may be provided or multiple kinds of gas supply sources may be provided. Likewise, the reservoir tank, circulation pipes, and the number of pumps are not limited to those in the drawings. Various instruments and control devices necessary for the operations of the substrate processing system may additionally be provided as required.

The invention is suitable for Atomic Layer Deposition. In Atomic Layer Distribution, the surface of a substrate is repeatedly exposed to a reactive substance to form an extremely low profile (thin) layer. In Atomic Layer Deposition, tens to hundreds of extremely low profile (thin) layers, each having a thickness on the order of a few atoms (nanometers), can be deposited on the surface of a substrate, allowing subtle and free adjustment of the film thickness. Atomic Layer Deposition uses a large amount of gas containing a reactive substance, but in one reaction process, only a small amount of reactive substance adheres to the target region of the substrate, and most of the reactive substance is left unreacted. According to the embodiment of the present invention, a gas containing an adequate amount of unreacted reactive substance can be utilized without being discharged directly to the outside. Therefore, wasting of reactive substances or carrier gases is prevented, a size increase in equipment such as pump devices for the gas transfer can be avoided, and energy consumption is kept in check. In such an embodiment, a plurality of film-forming gases are used as a first process gas. For example, in the case a film of silicon nitride is formed, a silane-based gas and an ammonia-based gas are supplied simultaneously or alternately. When they are supplied alternately, another reservoir is preferably provided.

Regarding a second process gas, a film-forming gas may be introduced into a reactor and mixed with a first process gas in the reservoir tank to adjust the concentration of the mixed gas, or a halogen-based cleaning gas may be supplied for cleaning the reactor 10 which requires no circulation after formation of a film. In particular, when the reaction of the film-forming gas and the cleaning gas will generate by-products, it is effective to supply the second process gas (cleaning gas) such that it bypasses the reservoir tank.

Although an embodiment of the invention is described above, the present invention is not limited to the foregoing embodiment, but may be carried out otherwise in various ways within the scope of the concept of the invention.

### DESCRIPTION OF REFERENCE NUMERALS

10: reactor
12: first gas supply source
14: reservoir tank
16: second gas supply source
18, 28, 32, 34, 40: valve
20: turbo-molecular pump
22, 26: dry pump
24, 30, 46: pipe
36: pressure pump
38: first circulation pipe
42: second circulation pump
44, 48: flow regulating valve

1. A substrate processing method using a substrate processing system comprising:
a gas supply source for supplying a first process gas containing a first reactive substance;
a reservoir tank for reserving the first process gas;
a reactor for exposing a substrate placed therein to the first process gas;
a first circulation pipe for introducing the first process gas from the reactor to the reservoir tank;
a second circulation pipe for introducing at least part of the first process gas from the reservoir tank to the reactor;
a flow regulating valve disposed in the second circulation pipe;
a pressure pump disposed between the reactor and the reservoir tank, the pressure pump being operative to generate a pressure difference between the reactor and the reservoir tank to cause the first process gas to flow from the reactor to the reservoir tank;
a pressure pump upstream valve disposed between the reactor and the pressure pump;
a pressure pump downstream valve disposed between the pressure pump and the reservoir tank;
a turbo-molecular pump connected to the reactor;
a turbo-molecular pump upstream valve disposed between the reactor and the turbo-molecular pump; and
a dry pump disposed downstream of the turbo-molecular pump, said substrate processing method comprising:
supplying the first process gas to the reservoir tank;
opening the turbo-molecular pump upstream valve after said supplying of the first process gas to the reservoir tank;
operating the turbo-molecular pump and the dry pump to reduce the pressure inside the reactor after said opening of the turbo-molecular pump upstream valve;
closing the turbo-molecular pump upstream valve after said operating of the turbo-molecular pump and the dry pump;
opening the pressure pump upstream valve, the pressure pump downstream valve, and the flow regulating valve; and closing any other valves connected to the reactor to allow the first process gas to flow from the reservoir tank to the reactor after said closing of the turbo-molecular pump upstream valve; and
operating the pressure pump to generate a pressure difference between the reactor and the reservoir tank to cause the first process gas to flow from the reactor to the reservoir tank, wherein the pressure pump is operated after said opening of the pressure pump upstream valve, the pressure pump downstream valve, and the flow regulating valve, and after said closing of the other valves connected to the reactor.

2. The substrate processing method according to claim 1, further comprising supplying a second process gas to the reactor such that the second process gas bypasses the reservoir tank, wherein the second process gas contains a second reactive substance that is different from the first reactive substance.

3. The substrate processing method according to claim 1, wherein the first process gas is continuously circulated through a circuit formed by the reactor, the pressure pump, the first circulation pipe, the reservoir tank, and the second circulation pipe.
